(19) United States
(12) Patent Application Publication
(10) Pub. No.: US 2024/0216950 A1
(43) Pub. Date: Jul. 4, 2024

(54) VIBRATION DEVICE

(71) Applicant: Murata Manufacturing Co., Ltd., Nagaokakyo-shi (JP)

(72) Inventors: Tatsuya NAMATSU, Nagaokakyo-shi (JP); Junichi HASHIMOTO, Nagaokakyo-shi (JP); Takao MOURI, Nagaokakyo-shi (JP)

(21) Appl. No.: 18/607,872

(22) Filed: Mar. 18, 2024

Related U.S. Application Data
(63) Continuation of application No. PCT/JP22/34789, filed on Sep. 16, 2022.

(30) Foreign Application Priority Data
Mar. 4, 2022 (JP) 2022-033111

(51) Int. Cl. B06B 1/02

(52) U.S. Cl. CPC B06B 1/02

(57) ABSTRACT

A vibration device including: a fixing member; a vibration member elastically coupled to the fixing member so as to vibrate in a left-right direction with respect to the fixing member; a film member having an upper main surface and a lower main surface arranged in an up-down direction and having a shape extending in the left-right direction, the film member constructed to expand and contract in the left-right direction when voltage is applied thereto, a left end portion of the film member being supported by the vibration member, and a right end portion of the film member being supported by the fixing member; a support member on the upper main surface or the lower main surface of the film member, wherein a boundary between the support member and the film member when viewed in the up-down direction includes an intersection portion intersecting a straight line extending in a front-back direction.

### CROSS REFERENCE TO RELATED APPLICATIONS

The present application is a continuation of International application No. PCT/JP2022/034789, filed Sep. 16, 2022, which claims priority to Japanese Patent Application No. 2022-033111, filed Mar. 4, 2022, the entire contents of each of which are incorporated herein by reference.

### TECHNICAL FIELD

The present invention relates to a vibration device including a film member.

### BACKGROUND ART

As an invention related to a conventional vibration device, for example, a vibration device described in Patent Document 1 is known. The vibration device includes a film, a frame member, a vibration unit, and a support member. The support member connects the frame member and the vibration unit. The vibration unit can vibrate with respect to the frame member. The film has a first end portion and a second end portion. The first end portion is fixed to the frame member. The second end portion is fixed to the vibration unit. When voltage is applied to the film, the film expands and contracts so that a distance between the first end portion and the second end portion changes. By the above, the vibration unit vibrates with respect to the frame member.

Patent Document 1: WO 2019/013164 A

### SUMMARY OF THE INVENTION

In the vibration device described in Patent Document 1, a thin film is used. For this reason, in the vibration device described in Patent Document 1, there is a demand for prevention of damage of the film.

In view of the above, an object of the present invention is to provide a vibration device capable of preventing damage of a film member.

A vibration device according to an aspect of the present invention includes: a fixing member; a vibration member elastically coupled to the fixing member so as to vibrate in a left-right direction with respect to the fixing member; a film member having an upper main surface and a lower main surface arranged in an up-down direction and having a shape extending in the left-right direction, the film member constructed to expand and contract in the left-right direction when voltage is applied thereto, a left end portion of the film member being supported by the vibration member, and a right end portion of the film member being supported by the fixing member; a support member on the upper main surface or the lower main surface of the film member, wherein a boundary between the support member and the film member when viewed in the up-down direction includes an intersection portion intersecting a straight line extending in a front-back direction.

A vibration device according to an aspect of the present invention includes: a fixing member; a vibration member elastically coupled to the fixing member so as to vibrate in a left-right direction with respect to the fixing member; a film member having an upper main surface and a lower main surface arranged in an up-down direction and having a shape extending in the left-right direction, the film member expanding and contracting in the left-right direction when voltage is applied thereto; a first vibration connection member fixed to a left end portion of the upper main surface of the film member and fixed to the vibration member; a second vibration connection member fixed to a left end portion of the lower main surface of the film member and fixed to the vibration member; a first fixed connection member fixed to a right end portion of the upper main surface of the film member and fixed to the fixing member; a second fixed connection member fixed to a right end portion of the lower main surface of the film member and fixed to the fixing member; a first reinforcing member on the upper main surface of the film member and connected to the first vibration connection member and the first fixed connection member; and a second reinforcing member on the lower main surface of the film member and connected to the second vibration connection member and the second fixed connection member, wherein the first vibration connection member, the second vibration connection member, the first fixed connection member, or the second fixed connection member have a notch, and the notch is in contact with a first boundary between the first reinforcing member and the first vibration connection member, a second boundary between the first reinforcing member and the first fixed connection member, a third boundary between the second reinforcing member and the second vibration connection member, or a fourth boundary between the second reinforcing member and the second fixed connection member.

In the present description, an axis or member extending in a front-back direction does not necessarily indicate only an axis or member parallel to the front-back direction. The axis or member extending in the front-back direction is an axis or member inclined within a range of ±45° with respect to the front-back direction. Similarly, an axis or member extending in an up-down direction is an axis or member inclined within a range of ±45° with respect to the up-down direction. An axis or member extending in a left-right direction is an axis or member inclined within a range of ±45° with respect to the left-right direction.

Hereinafter, a first member, a second member, and a third member are structures included in an electronic device. In the present description, that the first member is supported by the second member includes a case where the first member is attached to the second member so as not to be movable with respect to the second member (that is, the first member is fixed to or held by the second member), and a case where the first member is attached to the second member so as to be movable with respect to the second member. Further, that the first member is supported by the second member includes both a case where the first member is directly attached to the second member, and a case where the first member is attached to the second member with the third member interposed between them.

In the present description, the first member and the second member arranged in the front-back direction refer to a state below. When the first member and the second member are viewed in a direction perpendicular to the front-back direction, both the first member and the second member are in a state of being arranged on an optional straight line indicating the front-back direction. In the present description, the first member and the second member arranged in the front-back direction when viewed in the up-down direction refer to a state below. When the first member and the second member are viewed in the up-down direction, both the first member and the second member are arranged on an optional straight line indicating the front-back direction. In this case, when the first member and the second member are viewed from the left-right direction different from the up-down direction, one of the first member and the second member does not have to be arranged on an optional straight line indicating the front-back direction. The first member and the second member may be in contact with each other. The first member and the second member may be separated from each other. A third member may be present between the first member and the second member. This definition also applies to a direction other than the front-back direction.

In the present description, that the first member is arranged in front of the second member refers to a state below. A part of the first member is arranged in a region through which the second member passes when moving parallel in a forward direction. Therefore, the first member may be accommodated in the region through which the second member passes when moving parallel in the forward direction or may protrude from the region through which the second member passes when moving parallel in the forward direction. In this case, the first member and the second member are arranged in the front-back direction. This definition also applies to a direction other than the front-back direction.

In the present description, that the first member is arranged in front of the second member when viewed in the left-right direction refers to a state below. When viewed in the left-right direction, the first member and the second member are arranged in the front-back direction, and when viewed in the left-right direction, a portion facing the second member of the first member is arranged in front of the second member. In this definition, the first member and the second member do not have to be arranged in the front-back direction in three dimensions. This definition also applies to a direction other than the front-back direction.

In the present description, that the first member is arranged further to the front than the second member refers to a state below. The first member is arranged in front of a plane passing through a front end of the second member and orthogonal to the front-back direction. In this case, the first member and the second member may be arranged in the front-back direction and do not have to be arranged in the front-back direction. This definition also applies to a direction other than the front-back direction.

In the present description, each part of the first member is defined as described below unless otherwise specified. A front part of the first member means the front half of the first member. A back part of the first member means the back half of the first member. A left part of the first member means the left half of the first member. A right part of the first member means the right half of the first member. An upper part of the first member means the upper half of the first member. A lower part of the first member means the lower half of the first member. A front end of the first member means an end in the forward direction of the first member. A back end of the first member means an end in a backward direction of the first member. A left end of the first member means an end in a leftward direction of the first member. A right end of the first member means an end in a rightward direction of the first member. An upper end of the first member means an end in an upward direction of the first member. A lower end of the first member means an end in a downward direction of the first member. A front end part of the first member means the front end of the first member and the vicinity of the front end. A back end part of the first member means the back end of the first member and the vicinity of the back end. A left end part of the first member means the left end of the first member and the vicinity of the left end. A right end part of the first member means the right end of the first member and the vicinity of the right end. An upper end part of the first member means the upper end of the first member and the vicinity of the upper end. A lower end part of the first member means the lower end of the first member and the vicinity of the lower end.

In the present description, that the first member and the second member are electrically connected includes two meanings below. The first meaning is that direct current can flow through the first member and the second member as the first member and the second member are in physical contact with each other. The second meaning is that direct current can flow through the first member and the second member as the first member and the third member are in physical contact with each other and the third member and the second member are in physical contact with each other. In the second meaning, the first member and the second member may or may not be in physical contact with each other. In the second meaning, the third member may be a single member or may include a plurality of members.

According to a vibration device according to the present invention, a vibration device capable of preventing damage of a film member is provided.

### BRIEF EXPLANATION OF THE DRAWINGS

FIG. 1 is a perspective view of a vibration device 10.

FIG. 2 is a perspective view of the vicinity of a left end of a film member 22 of the vibration device 10.

FIG. 3 is a sectional view of the film member 22.

FIG. 4 is a top view of the vicinity of both ends of the film member 22 of the vibration device 10.

FIG. 5 is a bottom view of the vicinity of both ends of the film member 22 of the vibration device 10.

FIG. 6 is a top view of the vicinity of a left end of a film member 122 of a vibration device according to a comparative example.

FIG. 7 is a top view of the vicinity of both ends of the film member 22 of a vibration device 10a.

FIG. 8 is a bottom view of the vicinity of both ends of the film member 22 of the vibration device 10a.

FIG. 9 is a top view of the vicinity of both ends of the film member 22 of a vibration device 10b.

FIG. 10 is a bottom view of the vicinity of both ends of the film member 22 of the vibration device 10b.

FIG. 11 is a top view of the vicinity of both ends of the film member 22 of a vibration device 10c.

FIG. 12 is a top view of the vicinity of both ends of the film member 22 of a vibration device 10d.

FIG. 13 is a top view of the vicinity of a left end of the film member 22 of a vibration device 10e.

FIG. 14 is a bottom view of a first reinforcing member 24a, a third cushion member 24e, and a fourth cushion member 24f.

FIG. 15 is a top view of the vicinity of a left end of the film member 22 of a vibration device 10f.

FIG. 16 is a top view of the vicinity of a left end of the film member 22 of a vibration device 10g.

FIG. 17 is a top view of the vicinity of a left end of the film member 22 of a vibration device 10h.

FIG. 18 is a perspective view of the vicinity of a left end of the film member 22 of a vibration device 10i.

FIG. 19 is a top view of the vicinity of both ends of the film member 22 of a vibration device 10j.

### DETAILED DESCRIPTION OF THE INVENTION

### Embodiment

### [Structure of Vibration Device 10]

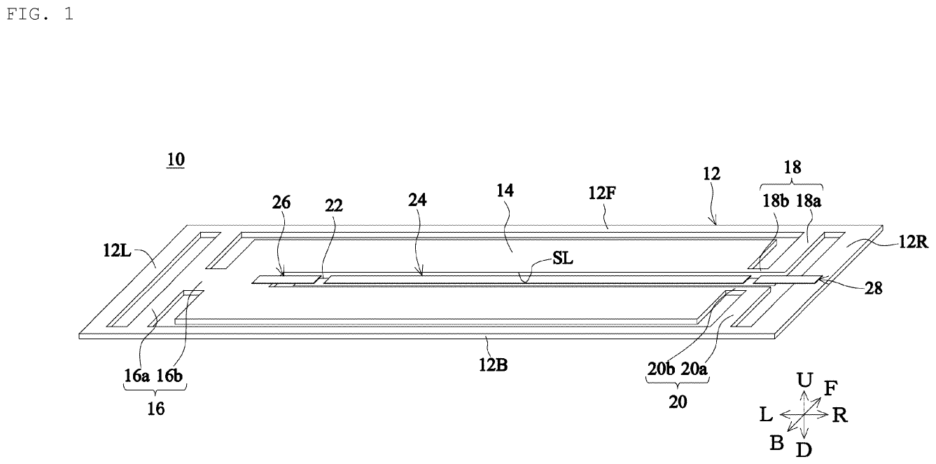

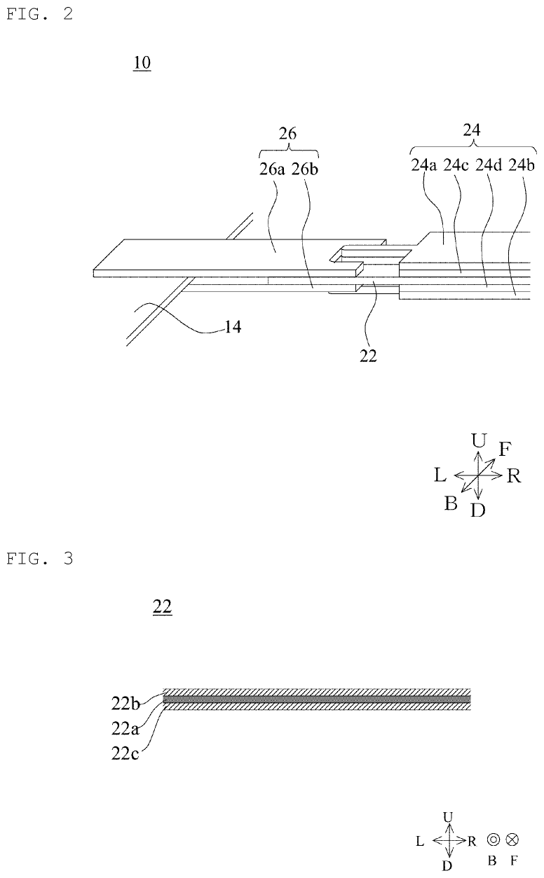

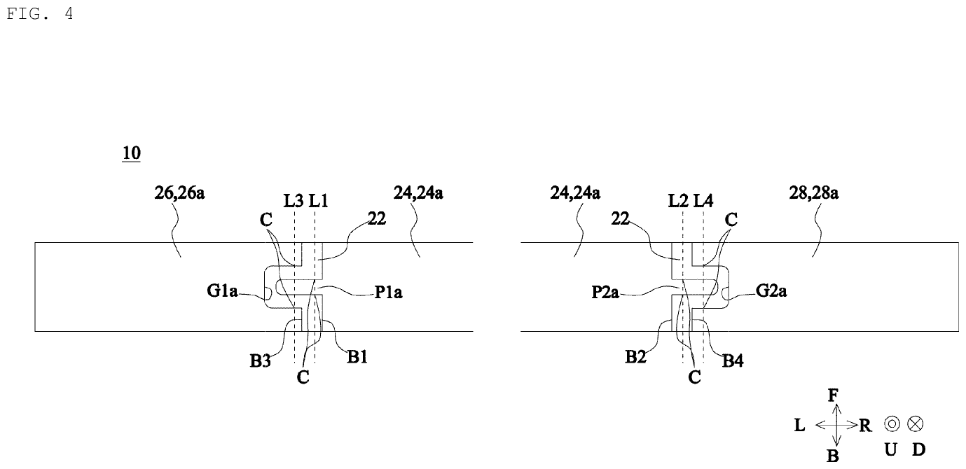

Hereinafter, a structure of a vibration device 10 according to an embodiment of the present invention will be described with reference to the drawings. FIG. 1 is a perspective view of the vibration device 10. In FIG. 1, the vicinity of a left end and the vicinity of a right end of a film member 22 are simplified. FIG. 2 is a perspective view of the vicinity of the left end of the film member 22 of the vibration device 10. FIG. 3 is a sectional view of the film member 22.

Further, in the present description, directions are defined as described below. In the vibration device 10, a direction in which an upper main surface and a lower main surface of the film member 22 are arranged is defined as an up-down direction. A direction in which a vibration member 14 vibrates is defined as a left-right direction. A direction orthogonal to the up-down direction and the left-right direction is defined as a front-back direction. The up-down direction, the left-right direction, and the front-back direction are orthogonal to each other. Note that the definition of directions in the present description is an example. Therefore, a direction at the time of actual use of the vibration device 10 does not need to coincide with a direction in the present description. Further, the up-down direction may be reversed in FIG. 1. Similarly, the left-right direction may be reversed in FIG. 1. The front-back direction may be reversed in FIG. 1.

In the present embodiment, as illustrated in FIG. 1, the vibration device 10 includes a fixing member 12, the vibration member 14, coupling members 16, 18, and 20, a film member 22, a reinforcing member 24, a vibration connection member 26, and a fixed connection member 28.

As illustrated in FIG. 1, the fixing member 12 has a plate shape. The fixing member 12 has an upper main surface and a lower main surface arranged in the up-down direction. The fixing member 12 has a rectangular frame shape when viewed in the up-down direction. Therefore, the fixing member 12 includes a front side portion 12F, a back side portion 12B, a left side portion 12L, and a right side portion 12R. The front side portion 12F and the back side portion 12B extend in the left-right direction. The left side portion 12L and the right side portion 12R extend in the front-back direction. By the above, the fixing member 12 is provided with an opening Op surrounded by the front side portion 12F, the back side portion 12B, the left side portion 12L, and the right side portion 12R.

The vibration member 14 is elastically coupled to the fixing member 12 to vibrate in the left-right direction with respect to the fixing member 12. More specifically, the vibration member 14 has a plate shape as illustrated in FIG. 1. The vibration member 14 has an upper main surface and a lower main surface arranged in the up-down direction. The vibration member 14 has a rectangular shape when viewed in the up-down direction. Therefore, the vibration member 14 has a front side, a back side, a left side, and a right side. Further, the vibration member 14 is provided with a slit SL extending in the left-right direction. The slit SL extends in the left direction from the center of a right side of the vibration member 14. The vibration member 14 having the above structure is located in the opening Op when viewed in the up-down direction.

The coupling member 16 elastically couples the vibration member 14 to the fixing member 12. More specifically, the coupling member 16 includes coupling portions 16a and 16b. The coupling portion 16a extends in the front-back direction. A front end of the coupling portion 16a is coupled to the vicinity of a left end of the front side portion 12F. A back end of the coupling portion 16a is coupled to the vicinity of a left end of the back side portion 12B. The coupling portion 16b extends in the left-right direction. A left end of the coupling portion 16b is coupled to the center in the front-back direction of the coupling portion 16a. A right end of the coupling portion 16b is connected to the center of a left side of the vibration member 14.

The coupling member 18 elastically couples the vibration member 14 to the fixing member 12. More specifically, the coupling member 18 includes coupling portions 18a and 18b. The coupling portion 18a extends in the front-back direction. A front end of the coupling portion 18a is coupled to the vicinity of a right end of the front side portion 12F. The coupling portion 18b extends in the left-right direction. A right end of the coupling portion 18b is coupled to a back end of the coupling portion 18a. A left end of the coupling portion 18b is coupled to the vicinity of the center of a right side of the vibration member 14.

The coupling member 20 elastically couples the vibration member 14 to the fixing member 12. More specifically, the coupling member 20 includes coupling portions 20a and 20b. The coupling portion 20a extends in the front-back direction. A back end of the coupling portion 20a is coupled to the vicinity of a right end of the back side portion 12B. The coupling portion 20b extends in the left-right direction. A right end of the coupling portion 20b is coupled to a front end of the coupling portion 20a. A left end of the coupling portion 20b is coupled to the vicinity of the center of a right side of the vibration member 14.

The vibration member 14 can be displaced in the left-right direction with respect to the fixing member 12 by elastic deformation of the coupling members 16, 18, and 20.

The fixing member 12, the vibration member 14, and the coupling members 16, 18, and 20 as described above are manufactured by processing of one plate-like member. Therefore, the fixing member 12, the vibration member 14, and the coupling members 16, 18, and 20 are inseparable single members. A material of the fixing member 12, a material of the vibration member 14, and a material of the coupling members 16, 18, and 20 are, for example, acrylic resin, polyethylene terephthalate (PET), polycarbonate (PC), fiber reinforced plastic (FRP), metal, and glass.

The film member 22 has an upper main surface and a lower main surface arranged in the up-down direction. The film member 22 has a shape extending in the left-right direction. The film member 22 has a film shape. Therefore, a thickness in the up-down direction of the film member 22 is much smaller than a length in the front-back direction of the film member 22 and a length in the left-right direction of the film member 22. By the above, the film member 22 can be easily bent in the up-down direction. The film member 22 extends in the left-right direction in the slit SL. A right end portion of the film member 22 is supported by the fixing member 12. A left end portion of the film member 22 is supported by the vibration member 14. However, a support structure to the fixing member 12 and the vibration member 14 for the film member 22 will be described later.

Further, the film member 22 expands and contracts in the left-right direction when voltage is applied. More specifically, as illustrated in FIG. 3, the film member 22 includes a film 22a, a first electrode 22b, and a second electrode 22c. The film 22a has an upper main surface and a lower main surface arranged in the up-down direction. In the present embodiment, the film 22a is a film containing polyvinylidene fluoride (PVDF).

The first electrode 22b is provided on an upper main surface of the film 22a. AC voltage changing between positive and negative is applied to the first electrode 22b. The second electrode 22c is provided on a lower main surface of the film 22a. Ground potential is connected to the second electrode 22c.

The film member 22 as described above expands in the left-right direction when positive voltage is applied to the first electrode 22b. On the other hand, the film member 22 contracts in the left-right direction when negative voltage is applied to the first electrode 22b. That is, a deformation amount of the film member 22 is proportional to voltage applied to the film member 22. By the above, the film member 22 vibrates in the left-right direction, for example, when AC voltage is applied to the film member 22.

The reinforcing member 24 is a member that prevents the film member 22 from bending in the up-down direction. Therefore, rigidity of the reinforcing member 24 is higher than rigidity of the film member 22. As illustrated in FIG. 2, the reinforcing member 24 includes a first reinforcing member 24a, a second reinforcing member 24b, a first cushion member 24c, and a second cushion member 24d.

The first cushion member 24c is fixed to an upper main surface of the film member 22. The first cushion member 24c has a band shape extending in the left-right direction when viewed in the up-down direction. However, a left end portion of the film member 22 protrudes in the left direction from the first cushion member 24c when viewed in the up-down direction. A right end portion of the film member 22 protrudes in the right direction from the first cushion member 24c when viewed in the up-down direction.

The first cushion member 24c is made from a material that hardly hinders expansion and contraction of the film member 22. A material of the first cushion member 24c is, for example, an elastic material such as rubber, polytetrafluoroethylene, polyethylene, polypropylene, polystyrene, polycarbonate, nylon, and the like.

The first reinforcing member 24a is fixed to an upper main surface of the first cushion member 24c. By the above, the first reinforcing member 24a is provided on an upper main surface of the film member 22. The first reinforcing member 24a has the same shape as the first cushion member 24c when viewed in the up-down direction. Therefore, the first reinforcing member 24a has a band shape extending in the left-right direction when viewed in the up-down direction. A left end portion of the film member 22 protrudes in the left direction from the first reinforcing member 24a when viewed in the up-down direction. A right end portion of the film member 22 protrudes in the right direction from the first reinforcing member 24a when viewed in the up-down direction.

The first reinforcing member 24a prevents bending in the up-down direction of the film member 22. In view of the above, Young's modulus of the first reinforcing member 24a is higher than Young's modulus of the first cushion member 24c. A material of the first reinforcing member 24a is metal such as stainless steel, a tungsten alloy, a titanium alloy, or the like.

The second cushion member 24d is fixed to a lower main surface of the film member 22. The second cushion member 24d has a band shape extending in the left-right direction when viewed in the up-down direction. A left end portion of the film member 22 protrudes in the left direction from the second cushion member 24d when viewed in the up-down direction. A right end portion of the film member 22 protrudes in the right direction from the second cushion member 24d when viewed in the up-down direction.

The second cushion member 24d is made from a material that hardly hinders expansion and contraction of the film member 22. A material of the second cushion member 24d is, for example, an elastic material such as rubber, polytetrafluoroethylene, polyethylene, polypropylene, polystyrene, polycarbonate, nylon, and the like.

The second reinforcing member 24b is fixed to a lower main surface of the second cushion member 24d. By the above, the second reinforcing member 24b is provided under a lower main surface of the film member 22. The second reinforcing member 24b has the same shape as the second cushion member 24d when viewed in the up-down direction. Therefore, the second reinforcing member 24b has a band shape extending in the left-right direction when viewed in the up-down direction. However, a left end portion of the film member 22 protrudes in the left direction from the second reinforcing member 24b when viewed in the up-down direction. A right end portion of the film member 22 protrudes in the right direction from the second reinforcing member 24b when viewed in the up-down direction.

The second reinforcing member 24b prevents bending in the up-down direction of the film member 22. In view of the above, Young's modulus of the second reinforcing member 24b is higher than Young's modulus of the second cushion member 24d. In view of the above, a material of the second reinforcing member 24b is metal such as stainless steel, a tungsten alloy, a titanium alloy, or the like.

Since the reinforcing member 24 has the above-described structure, a left end portion of the film member 22 protrudes in the left direction from the reinforcing member 24 when viewed in the up-down direction. Further, a right end portion of the film member 22 protrudes in the right direction from the reinforcing member 24 when viewed in the up-down direction.

The vibration connection member 26 causes the vibration member 14 to support a left end portion of the film member 22. The vibration connection member 26 includes a first vibration connection member 26a and a second vibration connection member 26b. The first vibration connection member 26a is fixed to an upper main surface of the film member 22 and is fixed to the vibration member 14. More specifically, the first vibration connection member 26a is fixed to a left end portion of an upper main surface of the film member 22. The first vibration connection member 26a is fixed to an upper main surface of the vibration member 14 at a left end of the slit SL. Then, the film member 22 protrudes in the right direction from the first vibration connection member 26a when viewed in the up-down direction.

The second vibration connection member 26b is fixed to a lower main surface of the film member 22 and is fixed to the vibration member 14. More specifically, the second vibration connection member 26b is fixed to a left end portion of a lower main surface of the film member 22. The second vibration connection member 26b is fixed to a lower main surface of the vibration member 14 at a left end of the slit SL. Then, the film member 22 protrudes in the right direction from the second vibration connection member 26b when viewed in the up-down direction.

Since the vibration connection member 26 has the above-described structure, the film member 22 protrudes in the right direction from the vibration connection member 26 when viewed in the up-down direction.

The fixed connection member 28 causes the fixing member 12 to support a right end portion of the film member 22. The fixed connection member 28 includes a first fixed connection member 28a and a second fixed connection member 28b. The first fixed connection member 28a is fixed to an upper main surface of the film member 22 and is fixed to the fixing member 12. More specifically, the first fixed connection member 28a is fixed to a right end portion of an upper main surface of the film member 22. The first fixed connection member 28a is fixed to the center in the front-back direction of an upper main surface of the right side portion 12R. Then, the film member 22 protrudes in the left direction from the first fixed connection member 28a when viewed in the up-down direction

The second fixed connection member 28b is fixed to a lower main surface of the film member 22 and is fixed to the fixing member 12. More specifically, the second fixed connection member 28b is fixed to a right end portion of a lower main surface of the film member 22. The second fixed connection member 28b is fixed to the center in the front-back direction of a lower main surface of the right side portion 12R. Then, the film member 22 protrudes in the left direction from the second fixed connection member 28b when viewed in the up-down direction

Since the fixed connection member 28 has the above-described structure, the film member 22 protrudes in the left direction from the fixed connection member 28 when viewed in the up-down direction.

A material of the vibration connection member 26 and the fixed connection member 28 is, for example, synthetic copolymer resin of acrylonitrile, butadiene, and styrene, polyethylene terephthalate, polycarbonate, polyimide, polyamide-imide, metal, or the like.

Operation of the vibration device 10 as described above will be described. The film member 22 vibrates in the left-right direction when AC voltage is applied to the film member 22. A left end portion of the film member 22 is supported by the vibration member 14, and a right end portion of the film member 22 is supported by the fixing member 12. For this reason, the vibration member 14 vibrates in the left-right direction with respect to the fixing member 12.

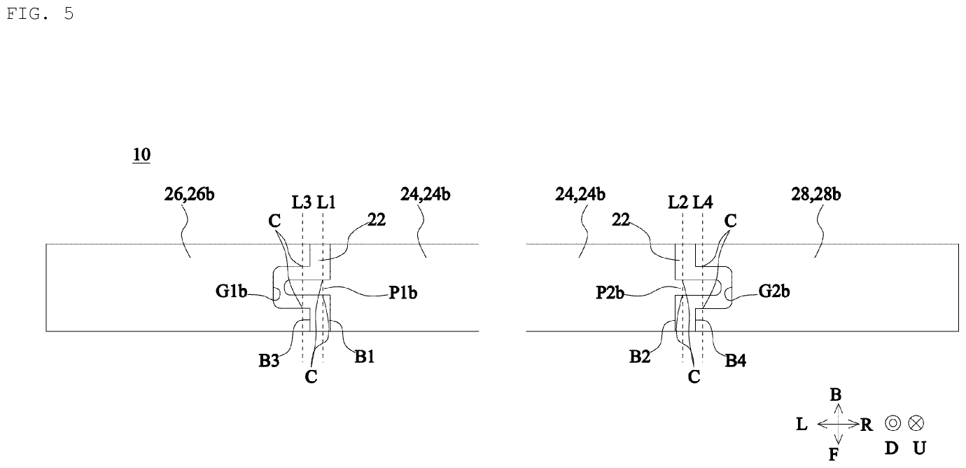

The vibration device 10 has a structure capable of preventing damage of the film member 22. Hereinafter, this structure will be described in detail. FIG. 4 is a top view of the vicinity of both ends of the film member 22 of the vibration device 10. FIG. 5 is a bottom view of the vicinity of both ends of the film member 22 of the vibration device 10.

In the vibration device 10, the film member 22 is supported by a support member provided on an upper main surface or a lower main surface of the film member 22. In the present embodiment, support members are the reinforcing member 24, the vibration connection member 26, and the fixed connection member 28. Then, a boundary between the support member (the reinforcing member 24, the vibration connection member 26, and the fixed connection member 28) and the film member 22 when viewed in the up-down direction includes an intersection portion C that intersects a straight line extending in the front-back direction.

More specifically, in the vibration device 10, a portion of a first boundary B1 between a left end portion of the reinforcing member 24 and the film member 22 when viewed in the up-down direction does not overlap a straight line L1 extending in the front-back direction. The first boundary B1 between the left end portion of the reinforcing member 24 and the film member 22 when viewed in the up-down direction includes an intersection portion C that intersects the straight line L1 extending in the front-back direction. That is, the first boundary B1 has a shape different from a straight line extending in the front-back direction when viewed in the up-down direction. In the present embodiment, as illustrated in FIG. 4, a portion of the first boundary B1 between a left end portion of the first reinforcing member 24a and the film member 22 when viewed in the up-down direction does not overlap the straight line L1 extending in the front-back direction. The first boundary B1 between the left end portion of the first reinforcing member 24a and the film member 22 when viewed in the up-down direction includes the intersection portion C that intersects the straight line L1 extending in the front-back direction. A protruding portion P1a protruding in the left direction when viewed in the up-down direction is formed at the first boundary B1. The protruding portion P1a is located at the center in the front-back direction of the first boundary B1.

Further, as illustrated in FIG. 5, a portion of the first boundary B1 between a left end portion of the second reinforcing member 24b and the film member 22 when viewed in the up-down direction does not overlap the straight line L1 extending in the front-back direction. The first boundary B1 between the left end portion of the second reinforcing member 24b and the film member 22 when viewed in the up-down direction includes the intersection portion C that intersects the straight line L1 extending in the front-back direction. A protruding portion P1b protruding in the left direction when viewed in the up-down direction is formed at the first boundary B1. The protruding portion P1b is located at the center in the front-back direction of the first boundary B1.

Further, a portion of a third boundary B3 between the vibration connection member 26 and the film member 22 when viewed in the up-down direction does not overlap a straight line L3 extending in the front-back direction. The third boundary B3 between the vibration connection member 26 and the film member 22 when viewed in the up-down direction includes the intersection portion C intersecting the straight line L3 extending in the front-back direction. That is, the third boundary B3 has a shape different from a straight line extending in the front-back direction when viewed in the up-down direction. In the present embodiment, as illustrated in FIG. 4, a portion of the third boundary B3 between the first vibration connection member 26a and the film member 22 when viewed in the up-down direction does not overlap the straight line L3 extending in the front-back direction. The third boundary B3 between the first vibration connection member 26a and the film member 22 when viewed in the up-down direction includes the intersection portion C intersecting the straight line L3 extending in the front-back direction. In the third boundary B3, a recessed portion G1a recessed in the left direction when viewed in the up-down direction is formed. The recessed portion G1a is located at the center in the front-back direction of the third boundary B3. Furthermore, a left end of the protruding portion P1a is located in a region surrounded by the recessed portion G1a. As a result, a portion of the third boundary B3 overlaps a portion of the first boundary B1 when viewed in the front-back direction.

Further, as illustrated in FIG. 5, a portion of the third boundary B3 between the second vibration connection member 26b and the film member 22 when viewed in the up-down direction does not overlap the straight line L3 extending in the front-back direction. The third boundary B3 between the second vibration connection member 26b and the film member 22 when viewed in the up-down direction includes the intersection portion C intersecting the straight line L3 extending in the front-back direction. In the third boundary B3, a recessed portion G1b recessed in the left direction when viewed in the up-down direction is formed. The recessed portion G1b is located at the center in the front-back direction of the third boundary B3. Furthermore, a left end of the protruding portion P1b is located in a region surrounded by the recessed portion G1b. As a result, a portion of the third boundary B3 overlaps a portion of the first boundary B1 when viewed in the front-back direction.

Note that a structure of a right end portion of the reinforcing member 24 is bilaterally symmetrical with a structure of a left end portion of the reinforcing member 24. A structure of the fixed connection member 28 is bilaterally symmetrical with a structure of the vibration connection member 26. For this reason, as illustrated in FIGS. 4 and 5, a second boundary B2 between a right end portion of the reinforcing member 24 and the film member 22 when viewed in the up-down direction includes that intersection portion C that intersects a straight line L2 extending in the front-back direction. A fourth boundary B4 between the fixed connection member 28 and the film member 22 when viewed in the up-down direction includes the intersection portion C intersecting a straight line L4 extending in the front-back direction. A portion of the fourth boundary B4 overlaps a portion of the second boundary B2 when viewed in the front-back direction. Specifically, protruding portions P2a and P2b protruding in the right direction when viewed in the up-down direction are formed at the second boundary B2. Recessed portions G2a and G2b recessed in the right direction when viewed in the up-down direction are formed at the fourth boundary B4. A right end of the protruding portion P2a is located in a region surrounded by the recessed portion G2a. A right end of the protruding portion P2b is located in a region surrounded by the recessed portion G2b. Further description of the second boundary B2 and the fourth boundary B4 will be omitted.

### [Effect]

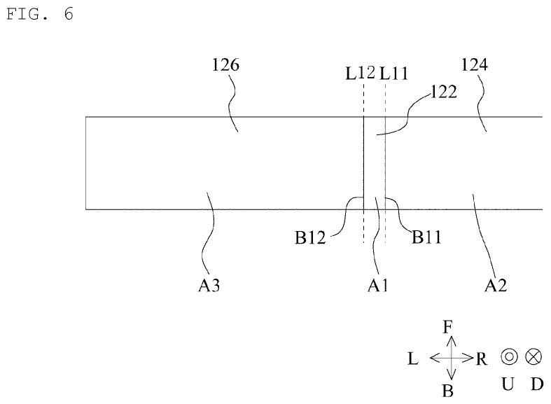

According to the vibration device 10, damage of the film member 22 can be prevented. FIG. 6 is a top view of the vicinity of a left end of a film member 122 of a vibration device according to a comparative example.

In the vibration device according to the comparative example illustrated in FIG. 6, an entire boundary B11 between a left end portion of a reinforcing member 124 and the film member 122 when viewed in the up-down direction overlaps a straight line L11 extending in the front-back direction. Further, an entire boundary B12 between a vibration connection member 126 and the film member 122 when viewed in the up-down direction overlaps a straight line L12 extending in the front-back direction. That is, the boundaries B11 and B12 are straight lines extending in the front-back direction. In such a vibration device, the film member 122 is likely to be damaged at the boundaries B11 and B12 as described below.

In the vibration device according to the comparative example, a region located between the boundary B11 and the boundary B12 in the film member 122 is defined as a region A1. In the film member 122, a region located further on the right than the boundary B11 is defined as a region A2. In the film member 122, a region located further on the left than the boundary B12 is defined as a region A3. In the vibration device according to the comparative example, the reinforcing member 124 is present in the region A2. Further, the vibration connection member 126 is present in the region A3. For this reason, the region A2 and the region A3 bend in the up-down direction less than the region A1. In this case, the region A1 significantly bends. In particular, the film member 122 tends to bend in the up-down direction at the boundaries B11 and B12.

Here, the film member 122 extends in the left-right direction. For this reason, when the film member 122 bends in the up-down direction, a polygonal line extending in the front-back direction is likely to be formed in the film member 122. When the boundaries B11 and B12 are straight lines extending in the front-back direction, a polygonal line is likely to be formed in the film member 122 at the boundaries B11 and B12. As a result, the film member 122 is likely to be damaged at the boundaries B11 and B12 as described below.

In view of the above, in the vibration device 10, a boundary between the reinforcing member 24 and the film member 22 when viewed in the up-down direction includes the intersection portion C intersecting a straight line extending in the front-back direction. More specifically, the first boundary B1 between a left end portion of the reinforcing member 24 and the film member 22 when viewed in the up-down direction includes the intersection portion C that intersects the straight line L1 extending in the front-back direction. By the above, a polygonal line extending in the front-back direction is hardly formed in the film member 22 at the first boundary B1. Therefore, the film member 22 is less likely to be damaged at the first boundary B1. For the same reason, the film member 22 is less likely to be damaged at the second boundary B2, the third boundary B3, and the fourth boundary B4.

Further, in the vibration device 10, damage to the film member 22 can also be prevented for a reason below. More specifically, a portion of the third boundary B3 overlaps a portion of the first boundary B1 when viewed in the front-back direction. By the above, either the reinforcing member 24 or the vibration connection member 26 is present when viewed in the front-back direction in an entire section of a left portion of the film member 22. Therefore, in the left portion of the film member 22, a portion having low rigidity is less likely to be generated. Therefore, a polygonal line extending in the front-back direction is further hardly formed in the left portion of the film member 22. As a result, the left portion of the film member 22 is less likely to be damaged. Further, in the vibration device 10, a portion of the fourth boundary B4 overlaps a portion of the second boundary B2 when viewed in the front-back direction. For this reason, a right portion of the film member 22 is less likely to be damaged for the same reason.

### First Variation

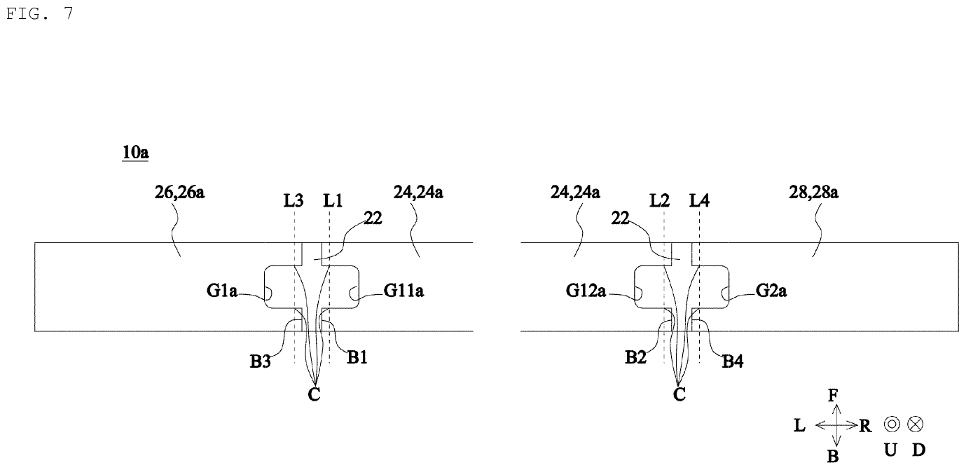

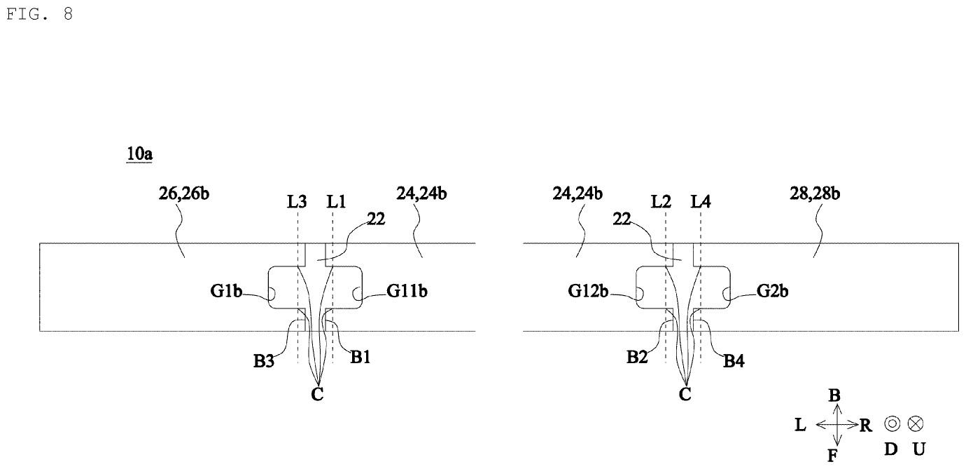

Hereinafter, a vibration device 10a according to a first variation will be described with reference to the drawings. FIG. 7 is a top view of the vicinity of both ends of the film member 22 of the vibration device 10a. FIG. 8 is a bottom view of the vicinity of both ends of the film member 22 of the vibration device 10a.

The vibration device 10a is different from the vibration device 10 in a shape of the first boundary B1 and a shape of the second boundary B2. More specifically, recessed portions G11a and G11b recessed in the right direction when viewed in the up-down direction are formed in the first boundary B1. The recessed portions G11a and G11b are located at the center in the front-back direction of the first boundary B1. Further, recessed portions G12a and G12b recessed in the left direction when viewed in the up-down direction are formed in the second boundary B2. The recessed portions G12a and G12b are located at the center in the front-back direction of the second boundary B2. Other structures of the vibration device 10a are the same as those of the vibration device 10, and are omitted from description. The vibration device 10a has the same function and effect as the vibration device 10.

### Second Variation

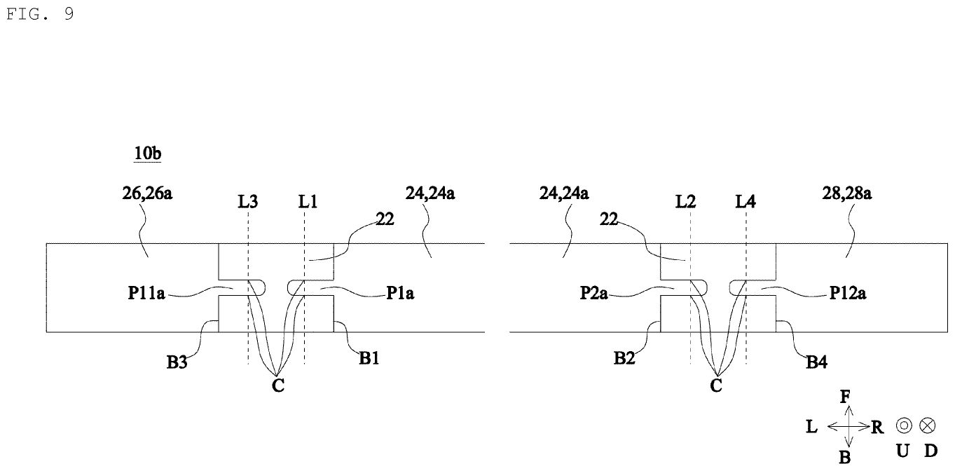

Hereinafter, a vibration device 10b according to a second variation will be described with reference to the drawings. FIG. 9 is a top view of the vicinity of both ends of the film member 22 of the vibration device 10b. FIG. 10 is a bottom view of the vicinity of both ends of the film member 22 of the vibration device 10b.

The vibration device 10b is different from the vibration device 10 in a shape of the third boundary B3 and a shape of the fourth boundary B4. More specifically, protruding portions P11a and P11b protruding in the right direction when viewed in the up-down direction are formed in the third boundary B3. The protruding portions P11a and P11b are located at the center in the front-back direction of the third boundary B3. Further, protruding portions P12a and P12b protruding in the left direction when viewed in the up-down direction are formed at the fourth boundary B4. The protruding portions P12a and P12b are located at the center in the front-back direction of the second boundary B2. Other structures of the vibration device 10b are the same as those of the vibration device 10, and are omitted from description. The vibration device 10b has the same function and effect as the vibration device 10.

### Third Variation

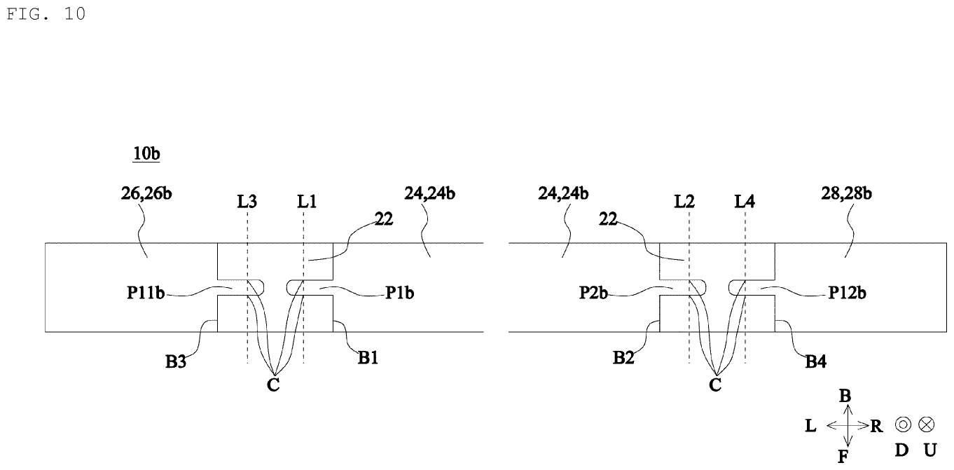

Hereinafter, a vibration device 10c according to a third variation will be described with reference to the drawings. FIG. 11 is a top view of the vicinity of both ends of the film member 22 of the vibration device 10c.

The vibration device 10c is different from the vibration device 10 in that a corner of a protruding portion and a corner of a recessed portion are not chamfered. Specifically, in the vibration device 10, for example, a corner of the protruding portions P1a and P2a and a corner of the recessed portions G1a and G2a are chamfered. On the other hand, in the vibration device 10c, for example, a corner of the protruding portions P1a and P2a and a corner of the recessed portions G1a and G2a are not chamfered. Note that, although not illustrated, a corner of the protruding portions P1b and P2b and a corner of the recessed portions G1b and G2b are not chamfered. Other structures of the vibration device 10c are the same as those of the vibration device 10, and are omitted from description. The vibration device 10c has the same function and effect as the vibration device 10.

### Fourth Variation

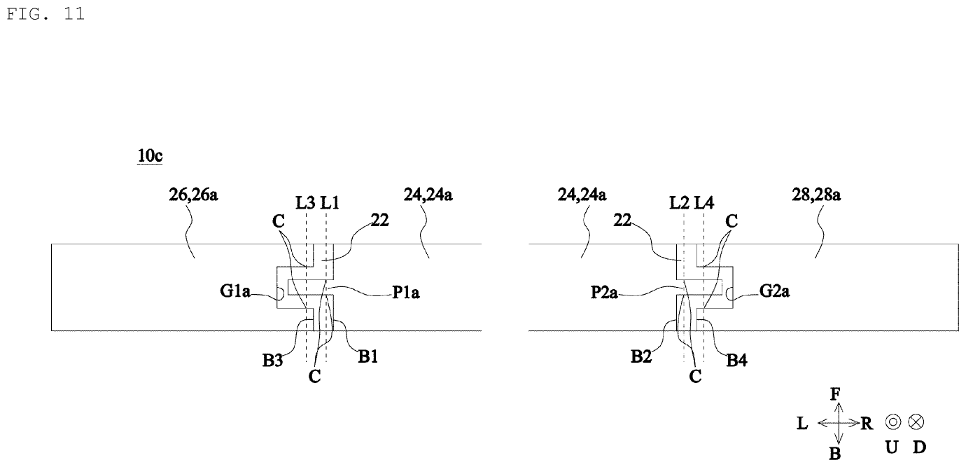

Hereinafter, a vibration device 10d according to a fourth variation will be described with reference to the drawings. FIG. 12 is a top view of the vicinity of both ends of the film member 22 of the vibration device 10d.

The vibration device 10d differs from the vibration device 10 in a shape of the reinforcing member 24, the vibration connection member 26, and the fixed connection member 28. Specifically, a width in the front-back direction of the reinforcing member 24, a width in the front-back direction of the vibration connection member 26, and a width in the front-back direction of the fixed connection member 28 are larger than a width in the front-back direction of the film member 22. Other structures of the vibration device 10d are the same as those of the vibration device 10, and are omitted from description. The vibration device 10d has the same function and effect as the vibration device 10.

### Fifth Variation

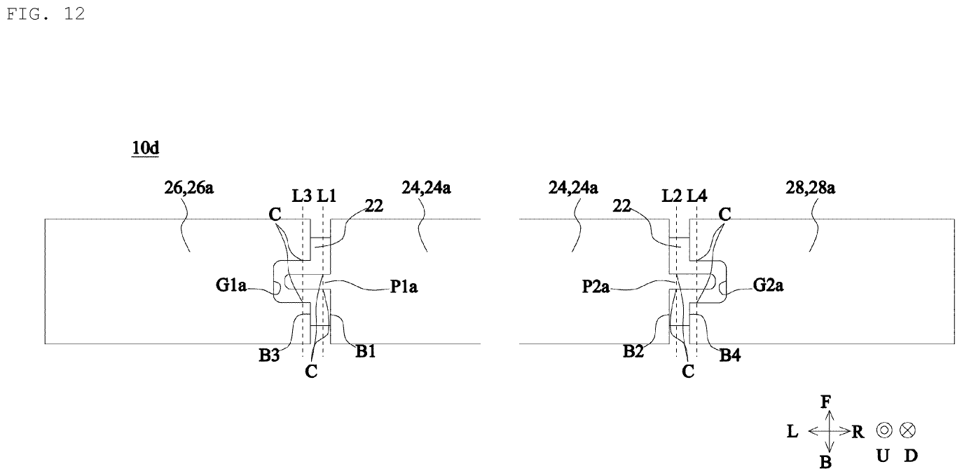

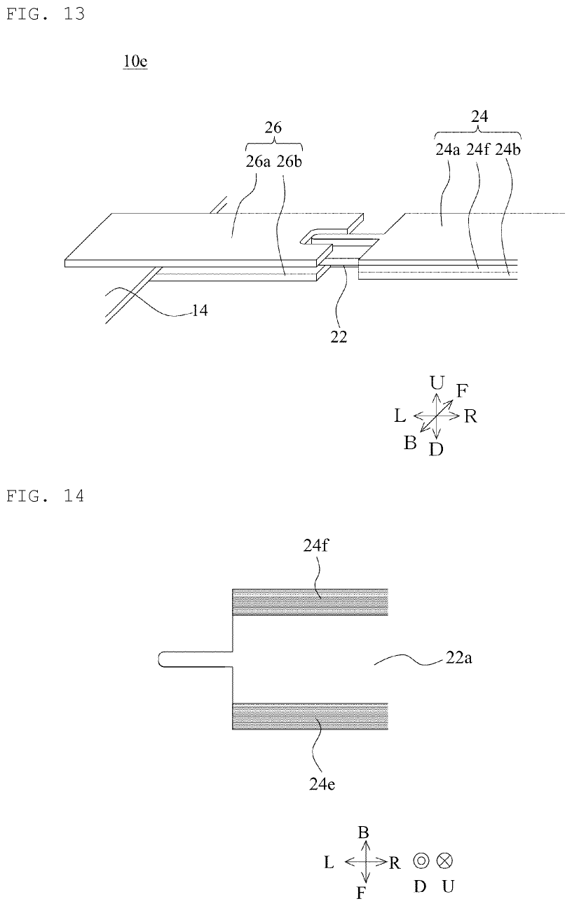

Hereinafter, a vibration device 10e according to a fifth variation will be described with reference to the drawings. FIG. 13 is a top view of the vicinity of a left end of the film member 22 of the vibration device 10e. FIG. 14 is a bottom view of the first reinforcing member 24a, a third cushion member 24e, and a fourth cushion member 24f.

The vibration device 10e is different from the vibration device 10 in including the third cushion member 24e and a fourth cushion member 24f instead of the first cushion member 24c and the second cushion member 24d. More specifically, a width in the front-back direction of the third cushion member 24e and a width in the front-back direction of the fourth cushion member 24f are smaller than a width in the front-back direction of the first reinforcing member 24a.

The third cushion member 24e extends along a front side of the first reinforcing member 24a and a front side of the second reinforcing member 24b. The third cushion member 24e is fixed to a lower main surface of the first reinforcing member 24a and an upper main surface of the second reinforcing member 24b.

The fourth cushion member 24f extends along a back side of the first reinforcing member 24a and a back side of the second reinforcing member 24b. The fourth cushion member 24f is fixed to a lower main surface of the first reinforcing member 24a and an upper main surface of the second reinforcing member 24b.

The film member 22 is located between the first reinforcing member 24a and the second reinforcing member 24b. Further, the film member 22 is located between the third cushion member 24e and the fourth cushion member 24f. However, the film member 22 is not fixed to the film member 22, the first reinforcing member 24a, or the second reinforcing member 24b so that the film member 22 can expand and contract in the left-right direction. The film member 22 is not fixed to the film member 22, the third cushion member 24e, or the fourth cushion member 24f. Other structures of the vibration device 10e are the same as those of the vibration device 10, and are omitted from description. The vibration device 10e has the same function and effect as the vibration device 10.

### Sixth Variation

Hereinafter, a vibration device 10f according to a sixth variation will be described with reference to the drawings. FIG. 15 is a top view of the vicinity of a left end of the film member 22 of the vibration device 10f.

The vibration device 10f differs from the vibration device 10e in a shape of the first boundary B1 and the third boundary B3. More specifically, a portion further to the front than the protruding portion P1a in the first boundary B1 extends in a right-front direction from the protruding portion P1a. A portion further to the back than the protruding portion P1a in the first boundary B1 extends from the protruding portion P1a in a right-back direction. A portion further to the front than the recessed portion G1a in the third boundary B3 extends in the right front direction from the recessed portion G1a. A portion further to the back than the recessed portion G1a in the third boundary B3 extends in the right back direction from the recessed portion G1a.

Note that, although not illustrated, a portion further to the front than the protruding portion P1b in the first boundary B1 extends in a right-front direction from the protruding portion P1b. A portion further to the back than the protruding portion P1b in the first boundary B1 extends from the protruding portion P1b in a right-back direction. A portion further to the front than the recessed portion G1b in the third boundary B3 extends in the right front direction from the recessed portion G1b. A portion further to the back than the recessed portion G1b in the third boundary B3 extends in the right back direction from the recessed portion G1b. Other structures of the vibration device 10f are the same as those of the vibration device 10e, and are omitted from description. The vibration device 10f has the same function and effect as the vibration device 10e.

### Seventh Variation

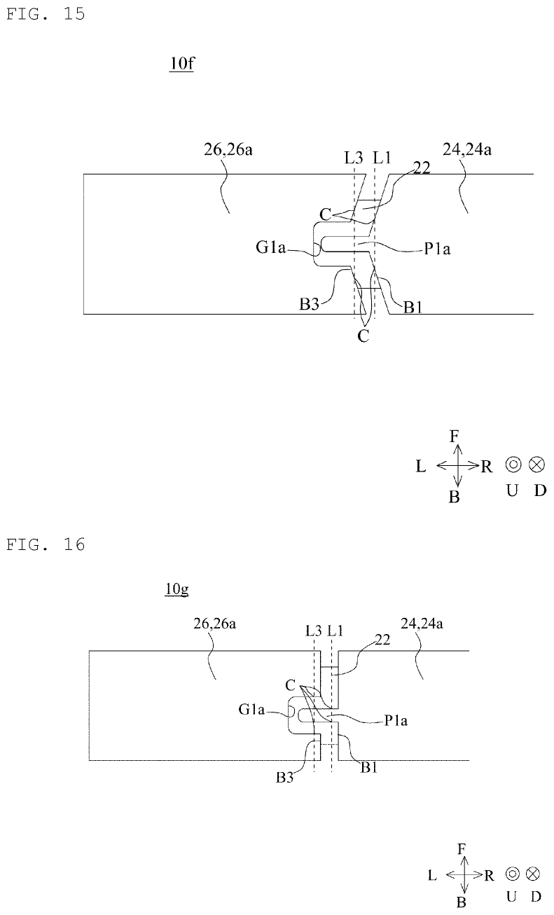

Hereinafter, a vibration device 10g according to a seventh variation will be described with reference to the drawings. FIG. 16 is a top view of the vicinity of a left end of the film member 22 of the vibration device 10g.

The vibration device 10g differs from the vibration device 10e in a shape of the first boundary B1 and the third boundary B3. More specifically, the center in the front-back direction of the protruding portion P1a is located further to the back than the center in the front-back direction of the first boundary B1. The center in the front-back direction of the recessed portion G1a is located further to the back than the center in the front-back direction of the third boundary B3.

Note that, although not illustrated, the center in the front-back direction of the protruding portion P1b is located further to the back than the center in the front-back direction of the first boundary B1. The center in the front-back direction of the recessed portion G1b is located further to the back than the center in the front-back direction of the third boundary B3. Other structures of the vibration device 10g are the same as those of the vibration device 10e, and are omitted from description. The vibration device 10g has the same function and effect as the vibration device 10e.

### Eighth Variation

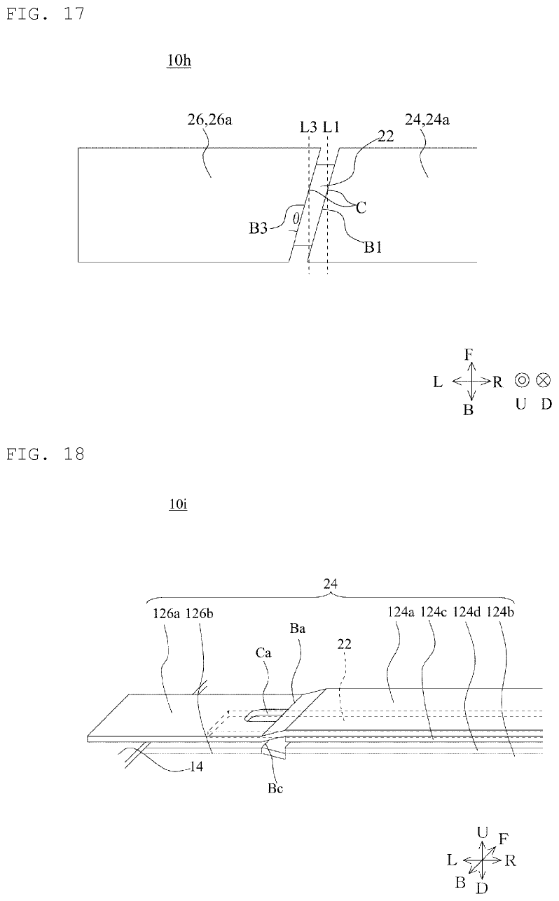

Hereinafter, a vibration device 10h according to an eighth variation will be described with reference to the drawings. FIG. 17 is a top view of the vicinity of a left end of the film member 22 of the vibration device 10h.

The vibration device 10h differs from the vibration device 10e in a shape of the first boundary B1 and the third boundary B3. More specifically, a straight line passing through a back end of the first boundary B1 and extending in the front-back direction is defined as the straight line L1. The first boundary B1 is inclined clockwise by θ with respect to the straight line L1. θ is 0 degrees to 90 degrees. A straight line passing through a back end of the third boundary B3 and extending in the front-back direction is defined as the straight line L3. The third boundary B3 is inclined clockwise by θ with respect to the straight line L3. θ is 0 degrees to 90 degrees. Further, a portion of the third boundary B3 overlaps a portion of the first boundary B1 when viewed in the front-back direction. Other structures of the vibration device 10h are the same as those of the vibration device 10e, and are omitted from description. The vibration device 10h has the same function and effect as the vibration device 10e.

### Ninth Variation

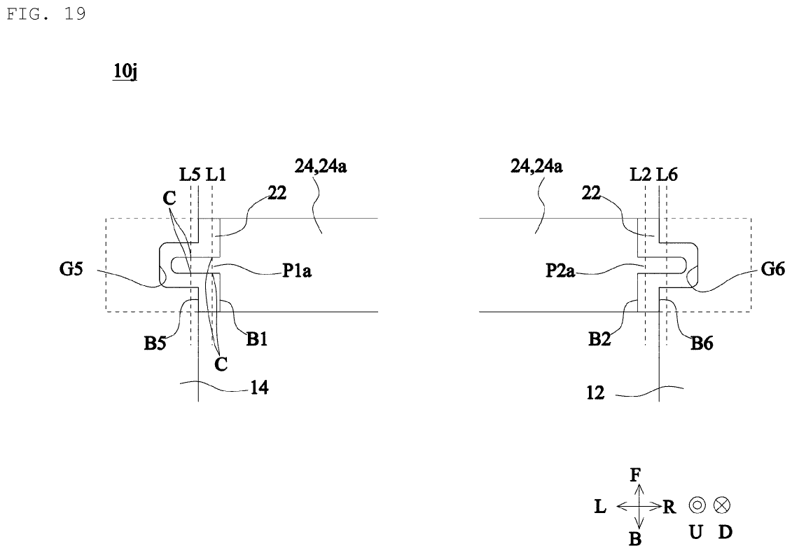

Hereinafter, a vibration device 10i according to a ninth variation will be described with reference to the drawings. FIG. 18 is a perspective view of the vicinity of a left end of the film member 22 of the vibration device 10i. Note that a structure of a right end portion of the first reinforcing member 124a and a structure of a right end portion of the first reinforcing member 124a are bilaterally symmetrical with a structure of a left end portion of the first reinforcing member 124a and a structure of a left end portion of the first reinforcing member 124a, respectively. A structure of a first fixed connection member 128a and a structure of a second fixed connection member 128b are bilaterally symmetrical with a structure of a first vibration connection member 126a and a structure of a second vibration connection member 126b, respectively. Therefore, illustration and description of the vicinity of a right end of the film member 22 of the vibration device 10i are omitted.

The vibration device 10i differs from the vibration device 10 in a structure of the reinforcing member 24. The reinforcing member 24 includes the first reinforcing member 124a, a second reinforcing member 124b, a first cushion member 124c, a second cushion member 124d, the first vibration connection member 126a, the second vibration connection member 126b, the first fixed connection member 128a (not illustrated), and the second fixed connection member 128b (not illustrated).

The first reinforcing member 124a, the second reinforcing member 124b, the first cushion member 124c, the second cushion member 124d, the first vibration connection member 126a, the second vibration connection member 126b, the first fixed connection member 128a, and the second fixed connection member 128b have the same structure as the first reinforcing member 24a, the second reinforcing member 24b, the first cushion member 24c, the second cushion member 24d, the first vibration connection member 26a, the second vibration connection member 26b, the first fixed connection member 28a, and the second fixed connection member 28b, respectively. However, the first reinforcing member 124a is connected to the first vibration connection member 126a and the first fixed connection member 128a. The second reinforcing member 124b is connected to the second vibration connection member 126b and the second fixed connection member 128b.

Further, the vibration device 10i has structures (D), (E), (F), and (G).

(D) A notch Ca in contact with a boundary Ba between the first reinforcing member 124a and the first vibration connection member 126a is provided in the first vibration connection member 126a.

(E) A notch Cb (not illustrated) in contact with a boundary Bb (not illustrated) between the first reinforcing member 124a and the first fixed connection member 128a is provided in the first fixed connection member 128a.

(F) A notch Cc (not illustrated) in contact with a boundary Bc between the second reinforcing member 124b and the second vibration connection member 126b is provided in the second vibration connection member 126b.

(G) A notch Cd (not illustrated) in contact with a boundary Bd between the second reinforcing member 124b and the second fixed connection member 128b is provided in the second fixed connection member 128b.

Definition of the notch Ca will be described. The notch Ca is a through hole penetrating the first vibration connection member 126a in the up-down direction. However, the notch Ca may be a recessed portion recessed in the back direction from a front side of the first vibration connection member 126a or a recessed portion recessed in the front direction from a back side of the first vibration connection member 126a. Definition of the notches Cb to Cd is also the same as the definition of the notch Ca.

Definition of the boundary Ba will be described. The first reinforcing member 124a is not directly fixed to the film member 22. On the other hand, the first vibration connection member 126a is directly fixed to the film member 22. Therefore, the boundary Ba is a right end of a portion where the film member 22 is directly fixed by the first vibration connection member 126a. Note that definition of the boundaries Bb, Bc, and Bd are also the same as the definition of the boundary Ba. Other structures of the vibration device 10i are the same as those of the vibration device 10, and omitted from description. The vibration device 10i has the same function and effect as the vibration device 10.

### Tenth Variation

Hereinafter, a vibration device 10j according to a tenth variation will be described with reference to the drawings. FIG. 19 is a top view of the vicinity of both ends of the film member 22 of the vibration device 10j.

The vibration device 10j differs from the vibration device 10 in not including the vibration connection member 26 and the fixed connection member 28. A left end portion of the film member 22 is fixed to the vibration member 14 when viewed in the up-down direction. A right end portion of the film member 22 is fixed to the fixing member 12 when viewed in the up-down direction. For fixing, for example, an adhesive, a double-sided tape, or the like is used.

Further, a fifth boundary B5 between the vibration member 14 and the film member 22 when viewed in the up-down direction includes the intersection portion C intersecting a straight line L5 extending in the front-back direction. Specifically, a recessed portion G5 recessed in the left direction when viewed in the up-down direction is formed in the fifth boundary B5. A protruding portion P1a protruding in the left direction when viewed in the up-down direction is formed at the first boundary B1. A left end of the protruding portion P1a is located in a region surrounded by the recessed portion G5. By the above, a portion of the fifth boundary B5 overlaps a portion of the first boundary B1 when viewed in the front-back direction.

Further, a sixth boundary B6 between the fixing member 12 and the film member 22 when viewed in the up-down direction includes the intersection portion C intersecting a straight line L6 extending in the front-back direction. Specifically, in the sixth boundary B6, a recessed portion G6 recessed in the right direction when viewed in the up-down direction is formed. The protruding portion P2a protruding in the right direction when viewed in the up-down direction is formed at the second boundary B2. A right end of the protruding portion P2a is located in a region surrounded by the recessed portion G6. By the above, a portion of the sixth boundary B6 overlaps a portion of the second boundary B2 when viewed in the front-back direction.

Other structures of the vibration device 10j are the same as those of the vibration device 10, and omitted from description. The vibration device 10j has the same function and effect as the vibration device 10.

### Other Embodiments

The vibration device according to the present invention is not limited to the vibration devices 10 and 10a to 10j, and can be modified within the scope of the gist of the present invention.

Further, structures of the vibration devices 10 and 10a to 10j may be optionally combined.

Note that the vibration device 10j only needs to include a structure of (D), (E), (F), or (G). Therefore, the vibration device 10j may include any one structure of (D), (E), (F), and (G), may include any two structures of (D), (E), (F), and (G), and may include any three structures of (D), (E), (F), and (G).

Note that the vibration devices 10 and 10a to 10h have structures (A) and (B).

(A) Each of the first boundary B1 between a left end portion of the reinforcing member 24 and the film member 22 when viewed in the up-down direction and the second boundary B2 between a right end portion of the reinforcing member 24 and the film member 22 when viewed in the up-down direction includes the intersection portion C intersecting the straight lines L1 and L2 extending in the front-back direction.

(B) Each of the third boundary B3 between the vibration connection member 26 and the film member 22 when viewed in the up-down direction and the fourth boundary B4 between the fixed connection member 28 and the film member 22 when viewed in the up-down direction includes the intersection portion C intersecting the straight lines L3 and L4 extending in the front-back direction.

However, the vibration devices 10 and 10a to 10g may have the structures (A) or (B). Therefore, the vibration devices 10 and 10a to 10g may have any one of the structures (A) and (B).

Note that the first boundary B1 between a left end portion of the reinforcing member 24 and the film member 22 when viewed in the up-down direction or the second boundary B2 between a right end portion of the reinforcing member 24 and the film member 22 when viewed in the up-down direction may include the intersection portion C intersecting the straight lines L1 and L2 extending in the front-back direction.

Note that the third boundary B3 between the vibration connection member 26 and the film member 22 when viewed in the up-down direction or the fourth boundary B4 between the fixed connection member 28 and the film member 22 when viewed in the up-down direction may include the intersection portion C intersecting the straight lines L3 and L4 extending in the front-back direction.

Further, the vibration device 10j has the structures (A) and (C).

(A) Each of the first boundary B1 between a left end portion of the reinforcing member 24 and the film member 22 when viewed in the up-down direction and the second boundary B2 between a right end portion of the reinforcing member 24 and the film member 22 when viewed in the up-down direction includes the intersection portion C intersecting the straight lines L1 and L2 extending in the front-back direction.

(C) Each of the fifth boundary B5 between the vibration member 14 and the film member 22 when viewed in the up-down direction and the sixth boundary B6 between the fixing member 12 and the film member 22 when viewed in the up-down direction includes the intersection portion C intersecting the straight lines L5 and L6 extending in the front-back direction.

However, the vibration device 10j may have the structure (A) or (C). Therefore, the vibration device 10j may have any one of the structures (A) and (C).

Note that, in the vibration device 10j, the first boundary B1 between a left end portion of the reinforcing member 24 and the film member 22 when viewed in the up-down direction or the second boundary B2 between a right end portion of the reinforcing member 24 and the film member 22 when viewed in the up-down direction may include the intersection portion C intersecting the straight lines L1 and L2 extending in the front-back direction.

Note that, in the vibration device 10j, the fifth boundary B5 between the vibration member 14 and the film member 22 when viewed in the up-down direction or the sixth boundary B6 between the fixing member 12 and the film member 22 when viewed in the up-down direction may include the intersection portion C intersecting the straight lines L5 and L6 extending in the front-back direction.

Note that, in the vibration device 10, the configuration may be such that only one of the protruding portion P1a of the first reinforcing member 24a and the protruding portion P1b of the second reinforcing member 24b is provided. The configuration may be such that only one of the protruding portion P2a of the first reinforcing member 24a and the protruding portion P2b of the second reinforcing member 24b is provided. The configuration may be such that only one of the recessed portion G1a of the first vibration connection member 26a and the recessed portion G1b of the second vibration connection member 26b is provided. The configuration may be such that only one of the recessed portion G2a of the first fixed connection member 28a and the recessed portion G2b of the second fixed connection member 28b is provided. Note that the same applies to the vibration devices 10a to 10i as in the vibration device 10.

Note that, in the vibration device 10, the configuration may be such that only one of the first vibration connection member 26a and the second vibration connection member 26b is provided. The configuration may be such that only one of the first fixed connection member 28a and the second fixed connection member 28b is provided. Note that the same applies to the vibration devices 10a to 10i as in the vibration device 10.

In the vibration devices 10 and 10a to 10j, the fixing member 12 does not need to have a rectangular frame shape when viewed in the up-down direction. Further, the fixing member 12, the vibration member 14, and the coupling members 16, 18, and 20 do not need to be manufactured by processing of one plate-like member. Therefore, the fixing member 12, the vibration member 14, and the coupling members 16, 18, and 20 maybe separate members.

In the vibration device 10 and 10a to 10j, the slit SL does not need to be provided.

Note that, in the vibration devices 10, 10c, 10d, 10e, 10f, 10g, and 10j, a recessed portion and a protruding portion may be interchanged.

Note that the reinforcing member 24 is not an essential constituent element.

Note that the vibration connection member 26 and the fixed connection member 28 are not constituent elements.

Note that, in the vibration device 10h, the third boundary B3 may be inclined counterclockwise by θ with respect to the straight line L3.

Note that AC voltage changing between positive and negative may be applied to the second electrode 22c, and ground potential may be connected to the second electrode 22c.

Note that, the film member 22 preferably expands and contracts in the left-right direction when voltage is applied. Therefore, the film member 22 is not limited to a film containing PVDF. The film member 22 maybe, for example, an electrostrictive film, an electret film, a composite film, an electroactive polymer film or the like. Note that, an electroactive film is a film that generates stress, or generates displacement by deforming, by electrical driving. Further, the film member 22 maybe piezoelectric ceramics that have been processed to be thin enough not to break.

Note that the configuration may be such that positive voltage in which potential periodically changes is applied to the first electrode 22b and ground potential is applied to the second electrode 22c, or negative voltage in which potential periodically changes is applied to the first electrode 22b and ground potential is applied to the second electrode 22c. Further, the configuration may be such that positive voltage in which potential periodically changes is applied to the second electrode 22c and ground potential is applied to the first electrode 22b, or negative voltage in which potential periodically changes is applied to the second electrode 22c and ground potential is applied to the first electrode 22b.

Further, the configuration may be such that positive voltage in which potential periodically changes is applied to the first electrode 22b, and negative voltage in which potential periodically changes is applied to the second electrode 22c, or negative voltage in which potential periodically changes is applied to the first electrode 22b, and positive voltage in which potential periodically changes is applied to the second electrode 22c. In this case, positive voltage and negative voltage have the same period.

### DESCRIPTION OF REFERENCE SYMBOLS

10, 10a to 10j: Vibration device
12: Fixing member
12B: Back side portion
12F: Front side portion
12L: Left side portion
12R: Right side portion
14: Vibration member
16, 18, 20: Coupling member
16a, 16b, 18a, 18b, 20a, 20b: Coupling portion
22: Film member
22a: Film
22b: First electrode
22c: Second electrode
24: Reinforcing member
24a: First reinforcing member
24b: Second reinforcing member
24c: First cushion member
24d: Second cushion member
24e: Third cushion member
24f: Fourth cushion member
26: Vibration connection member
26a: First vibration connection member
26b: Second vibration connection member
28: Fixed connection member
28a: First fixed connection member
28b: Second fixed connection member
122: Film member
124: Reinforcing member
124a: First reinforcing member
124b: Second reinforcing member
126: Vibration connection member
126a: First vibration connection member
126b: Second vibration connection member
128a: First fixed connection member
128b: Second fixed connection member
B1: First boundary
B2: Second boundary
B3: Third boundary
B4: Fourth boundary
B5: Fifth boundary
B6: Sixth boundary
Ba to Bd: Boundary
C: Intersection portion
Ca to Cd: Notch
G1a, G1b, G2a, G2a, G5, G6: Recessed portion
Op: Opening
P1a, P1b, P2a, P2b: Protruding portion
SL: Slit

1. A vibration device comprising:
a fixing member;
a vibration member elastically coupled to the fixing member so as to vibrate in a left-right direction with respect to the fixing member;
a film member having an upper main surface and a lower main surface arranged in an up-down direction and having a shape extending in the left-right direction, the film member constructed to expand and contract in the left-right direction when voltage is applied thereto, a left end portion of the film member being supported by the vibration member, and a right end portion of the film member being supported by the fixing member;
a support member on the upper main surface or the lower main surface of the film member, wherein
a boundary between the support member and the film member when viewed in the up-down direction includes an intersection portion intersecting a straight line extending in a front-back direction.

2. The vibration device according to claim 1, wherein support member comprises:
a first reinforcing member on the upper main surface of the film member; and
a second reinforcing member on the lower main surface of the film member, wherein
the left end portion of the film member protrudes in a left direction from the support member when viewed in the up-down direction,
the right end portion of the film member protrudes in a right direction from the support member when viewed in the up-down direction,
a first boundary between a left end portion of the support member and the film member when viewed in the up-down direction or a second boundary between a right end portion of the support member and the film member when viewed in the up-down direction includes the intersection portion.

3. The vibration device according to claim 1, wherein the support member is one of:
a fixed connection member including a first fixed connection member fixed to the upper main surface of the film member and fixed to the fixing member, and a second fixed connection member fixed to the lower main surface of the film member and fixed to the fixing member; or
a vibration connection member including a first vibration connection member fixed to the upper main surface of the film member and fixed to the vibration member, and a second vibration connection member fixed to the lower main surface of the film member and fixed to the vibration member, wherein
the film member protrudes in the left direction from the fixed connection member when viewed in the up-down direction,
the film member protrudes in the right direction from the vibration connection member when viewed in the up-down direction, and
a third boundary between the vibration connection member and the film member when viewed in the up-down direction or a fourth boundary between the fixed connection member and the film member when viewed in the up-down direction includes the intersection portion.

4. The vibration device according to claim 1, wherein
the support member is one of the vibration member or the fixing member,
the left end portion of the film member is fixed to the vibration member when viewed in the up-down direction,
the right end portion of the film member is fixed to the fixing member when viewed in the up-down direction, and
a fifth boundary between the vibration member and the film member when viewed in the up-down direction or a sixth boundary between the fixing member and the film member when viewed in the up-down direction includes the intersection portion.

5. The vibration device according to claim 2, further comprising:
a fixed connection member including a first fixed connection member fixed to the upper main surface of the film member and fixed to the fixing member, and a second fixed connection member fixed to the lower main surface of the film member and fixed to the fixing member; or
a vibration connection member including a first vibration connection member fixed to the upper main surface of the film member and fixed to the vibration member, and a second vibration connection member fixed to the lower main surface of the film member and fixed to the vibration member, wherein
the film member protrudes in the left direction from the fixed connection member when viewed in the up-down direction,
the film member protrudes in the right direction from the vibration connection member when viewed in the up-down direction,
the intersection portion is a first intersection portion,
a third boundary between the vibration connection member and the film member when viewed in the up-down direction or a fourth boundary between the fixed connection member and the film member when viewed in the up-down direction includes a second intersection portion intersecting a straight line extending in a front-back direction, and
a portion of the third boundary overlaps a portion of the first boundary when viewed in the front-back direction, or a portion of the fourth boundary overlaps a portion of the second boundary when viewed in the front-back direction.

6. The vibration device according to claim 5, wherein
a recessed portion recessed in the left direction when viewed in the up-down direction is present in the third boundary,
a protruding portion protruding in the left direction when viewed in the up-down direction is present in the first boundary, and
a left end of the protruding portion is located in a region surrounded by the recessed portion.

7. The vibration device according to claim 5, wherein
a recessed portion recessed in the right direction when viewed in the up-down direction is present in the fourth boundary,
a protruding portion protruding in the right direction when viewed in the up-down direction is present in the second boundary, and
a right end of the protruding portion is located in a region surrounded by the recessed portion.

8. The vibration device according to claim 2, wherein
the intersection portion is a first intersection portion,
the left end portion of the film member is fixed to the vibration member when viewed in the up-down direction,
the right end portion of the film member is fixed to the fixing member when viewed in the up-down direction,
a fifth boundary between the vibration member and the film member when viewed in the up-down direction or a sixth boundary between the fixing member and the film member when viewed in the up-down direction includes a second intersection portion intersecting a straight line extending in a front-back direction, and
a portion of the fifth boundary overlaps a portion of the first boundary when viewed in the front-back direction, or a portion of the sixth boundary overlaps a portion of the second boundary when viewed in the front-back direction.

9. The vibration device according to claim 8, wherein
a recessed portion recessed in the left direction when viewed in the up-down direction is present in the fifth boundary,
a protruding portion protruding in the left direction when viewed in the up-down direction is present in the first boundary, and
a left end of the protruding portion is located in a region surrounded by the recessed portion.

10. The vibration device according to claim 8, wherein
a recessed portion recessed in the right direction when viewed in the up-down direction is present in the sixth boundary,
a protruding portion protruding in the right direction when viewed in the up-down direction is present in the second boundary, and
a right end of the protruding portion is located in a region surrounded by the recessed portion.

11. The vibration device according to claim 1, wherein the boundary is inclined clockwise with respect to the straight line at an angle θ of 0 degrees to 90 degrees.

12. The vibration device according to claim 1, the support member includes:
a fixed connection member including a first fixed connection member fixed to the upper main surface of the film member and fixed to the fixing member, and a second fixed connection member fixed to the lower main surface of the film member and fixed to the fixing member; and
a vibration connection member including a first vibration connection member fixed to the upper main surface of the film member and fixed to the vibration member, and a second vibration connection member fixed to the lower main surface of the film member and fixed to the vibration member, wherein
the intersection portion is a first intersection portion,
the film member protrudes in the left direction from the fixed connection member when viewed in the up-down direction,
the film member protrudes in the right direction from the vibration connection member when viewed in the up-down direction,
a third boundary between the vibration connection member and the film member when viewed in the up-down direction includes the first intersection portion, and
a fourth boundary between the fixed connection member and the film member when viewed in the up-down direction includes a second intersection portion intersecting a straight line extending in a front-back direction.

13. The vibration device according to claim 2, further comprising:
a fixed connection member including a first fixed connection member fixed to the upper main surface of the film member and fixed to the fixing member, and a second fixed connection member fixed to the lower main surface of the film member and fixed to the fixing member; and
a vibration connection member including a first vibration connection member fixed to the upper main surface of the film member and fixed to the vibration member, and a second vibration connection member fixed to the lower main surface of the film member and fixed to the vibration member, wherein
the film member protrudes in the left direction from the fixed connection member when viewed in the up-down direction,
the film member protrudes in the right direction from the vibration connection member when viewed in the up-down direction,
the intersection portion is a first intersection portion,
a third boundary between the vibration connection member and the film member when viewed in the up-down direction includes a second intersection portion intersecting a straight line extending in a front-back direction,
a fourth boundary between the fixed connection member and the film member when viewed in the up-down direction includes a third intersection portion intersecting a straight line extending in a front-back direction,
a portion of the third boundary overlaps a portion of the first boundary when viewed in the front-back direction, and
a portion of the fourth boundary overlaps a portion of the second boundary when viewed in the front-back direction.

14. The vibration device according to claim 13, wherein
a recessed portion recessed in the left direction when viewed in the up-down direction is present in the third boundary,
a protruding portion protruding in the left direction when viewed in the up-down direction is present in the first boundary, and
a left end of the protruding portion is located in a region surrounded by the recessed portion.

15. The vibration device according to claim 13, wherein
a recessed portion recessed in the right direction when viewed in the up-down direction is present in the fourth boundary,
a protruding portion protruding in the right direction when viewed in the up-down direction is present in the second boundary, and
a right end of the protruding portion is located in a region surrounded by the recessed portion.

16. The vibration device according to claim 2, wherein
the intersection portion is a first intersection portion,
the left end portion of the film member is fixed to the vibration member when viewed in the up-down direction,
the right end portion of the film member is fixed to the fixing member when viewed in the up-down direction,
a fifth boundary between the vibration member and the film member when viewed in the up-down direction includes a second intersection portion intersecting a straight line extending in a front-back direction,
a sixth boundary between the fixing member and the film member when viewed in the up-down direction includes a third intersection portion intersecting a straight line extending in a front-back direction,
a portion of the fifth boundary overlaps a portion of the first boundary when viewed in the front-back direction, and
a portion of the sixth boundary overlaps a portion of the second boundary when viewed in the front-back direction.

17. The vibration device according to claim 16, wherein
a recessed portion recessed in the left direction when viewed in the up-down direction is present in the fifth boundary,
a protruding portion protruding in the left direction when viewed in the up-down direction is present in the first boundary, and
a left end of the protruding portion is located in a region surrounded by the recessed portion.

18. The vibration device according to claim 16, wherein
a recessed portion recessed in the right direction when viewed in the up-down direction is present in the sixth boundary,
a protruding portion protruding in the right direction when viewed in the up-down direction is present in the second boundary, and
a right end of the protruding portion is located in a region surrounded by the recessed portion.

19. A vibration device comprising:
a fixing member;
a vibration member elastically coupled to the fixing member so as to vibrate in a left-right direction with respect to the fixing member;
a film member having an upper main surface and a lower main surface arranged in an up-down direction and having a shape extending in the left-right direction, the film member expanding and contracting in the left-right direction when voltage is applied thereto;
a first vibration connection member fixed to a left end portion of the upper main surface of the film member and fixed to the vibration member;
a second vibration connection member fixed to a left end portion of the lower main surface of the film member and fixed to the vibration member;
a first fixed connection member fixed to a right end portion of the upper main surface of the film member and fixed to the fixing member;
a second fixed connection member fixed to a right end portion of the lower main surface of the film member and fixed to the fixing member;
a first reinforcing member on the upper main surface of the film member and connected to the first vibration connection member and the first fixed connection member; and
a second reinforcing member on the lower main surface of the film member and connected to the second vibration connection member and the second fixed connection member, wherein
the first vibration connection member, the second vibration connection member, the first fixed connection member, or the second fixed connection member have a notch, and
the notch is in contact with a first boundary between the first reinforcing member and the first vibration connection member, a second boundary between the first reinforcing member and the first fixed connection member, a third boundary between the second reinforcing member and the second vibration connection member, or a fourth boundary between the second reinforcing member and the second fixed connection member.
